(19) United States
(12) Patent Application Publication
(10) Pub. No.: US 2019/0295886 A1
(43) Pub. Date: Sep. 26, 2019

(54) SEMICONDUCTOR DEVICE

(71) Applicant: Samsung Electronics Co., Ltd., Suwon-si (KR)

(72) Inventors: Byungha CHOI, Suwon-si (KR); Yuri MASUOKA, Seongnam-si (KR); Yul LEE, Seoul (KR)

(21) Appl. No.: 16/238,606

(22) Filed: Jan. 3, 2019

(30) Foreign Application Priority Data
Mar. 21, 2018 (KR) 10-2018-0032791

(51) Int. Cl. H01L 21/768; H01L 29/78; H01L 29/06; H01L 29/08; H01L 29/45; H01L 23/535; H01L 29/66; H01L 21/02; H01L 21/285

(52) U.S. Cl. CPC H01L 21/76834; H01L 29/7851; H01L 29/0653; H01L 29/0847; H01L 29/7848; H01L 21/76895; H01L 23/535; H01L 29/66795; H01L 29/66636; H01L 21/02164; H01L 21/28518; H01L 29/45

(57) ABSTRACT

A semiconductor device including an active pattern on a substrate; a gate structure crossing the active pattern; a source/drain pattern on the active pattern at a side of the gate structure; a contact plug on the source/drain pattern; and a conductive pattern between the source/drain pattern and the contact plug, wherein the source/drain pattern includes a barrier layer adjacent to the conductive pattern, and wherein the barrier layer includes an oxygen atom.

### CROSS-REFERENCE TO RELATED APPLICATION

Korean Patent Application No. 10-2018-0032791 filed on Mar. 21, 2018, in the Korean Intellectual Property Office, and entitled: “Semiconductor Device,” is incorporated by reference herein in its entirety.

### BACKGROUND

### 1. Field

Embodiments relate to a semiconductor device.

### 2. Description of the Related Art

A semiconductor device may include an integrated circuit including metal oxide semiconductor field effect transistors (MOSFETs).

### SUMMARY

The embodiments may be realized by providing a semiconductor device including an active pattern on a substrate; a gate structure crossing the active pattern; a source/drain pattern on the active pattern at a side of the gate structure; a contact plug on the source/drain pattern; and a conductive pattern between the source/drain pattern and the contact plug, wherein the source/drain pattern includes a barrier layer adjacent to the conductive pattern, and wherein the barrier layer includes an oxygen atom.

The embodiments may be realized by providing a semiconductor device including an active pattern on a substrate; a gate structure crossing the active pattern; a source/drain pattern on the active pattern at a side of the gate structure; and a conductive pattern on the source/drain pattern, wherein the source/drain pattern includes a first semiconductor pattern and a second semiconductor pattern sequentially stacked on the active pattern; and a barrier layer between the conductive pattern and at least a portion of the second semiconductor pattern, and wherein the barrier layer includes an oxygen atom.

### BRIEF DESCRIPTION OF THE DRAWINGS

Features will be apparent to those of skill in the art by describing in detail exemplary embodiments with reference to the attached drawings in which:

FIG. 1 illustrates a plan view showing a semiconductor device according to exemplary embodiments.

FIG. 2 illustrates a cross-sectional view taken along lines IT and II-IF of FIG. 1.

FIG. 3A illustrates an enlarged view showing section A of FIG. 2.

FIGS. 3B, 3C, and 3D illustrate enlarged views showing section A of FIG. 2, according to exemplary embodiments.

FIGS. 4 to 8 illustrate cross-sectional views taken along lines IT and II-IF of FIG. 1, showing stages in a method of manufacturing a semiconductor device according to exemplary embodiments.

FIG. 9A illustrates an enlarged view showing section B of FIG. 8.

FIGS. 9B to 9D illustrate enlarged views showing section B of FIG. 8, showing stages in a method of manufacturing a semiconductor device according to exemplary embodiments.

FIG. 10 illustrates a plan view showing a semiconductor device according to exemplary embodiments.

FIG. 11 illustrates a cross-sectional view taken along lines IT and II-II′ of FIG. 10.

FIGS. 12 to 16 illustrate cross-sectional views taken along lines I-I′ and II-II′ of FIG. 10, showing stages in a method of manufacturing a semiconductor device according to exemplary embodiments.

### DETAILED DESCRIPTION

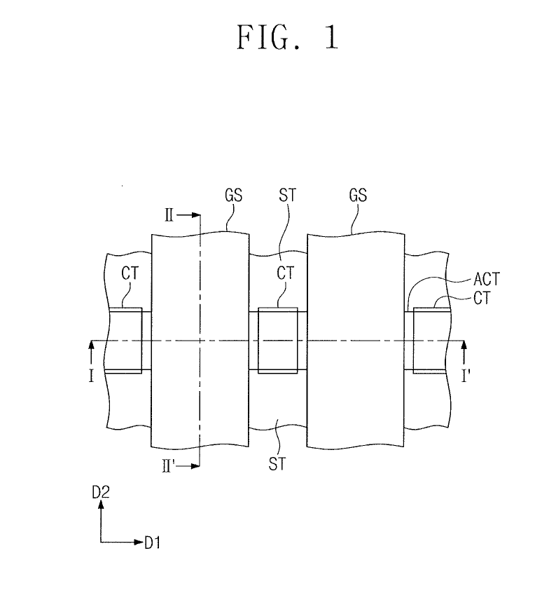

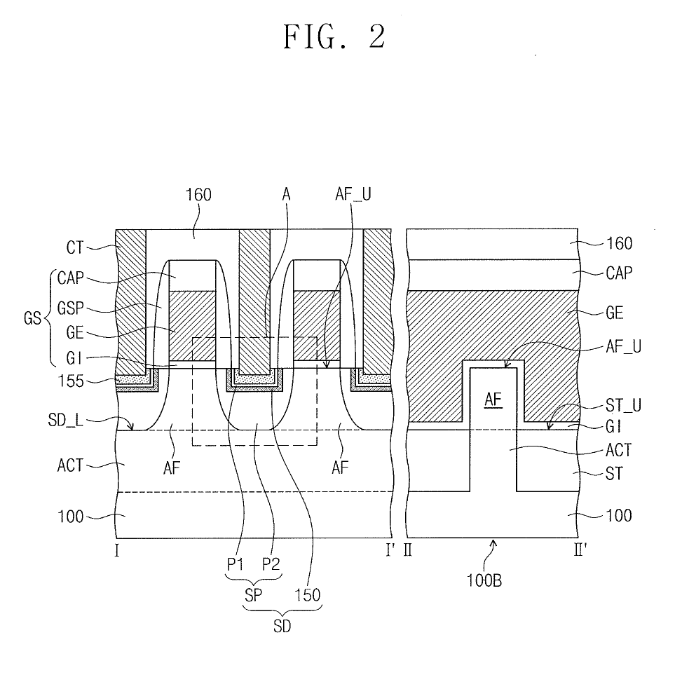

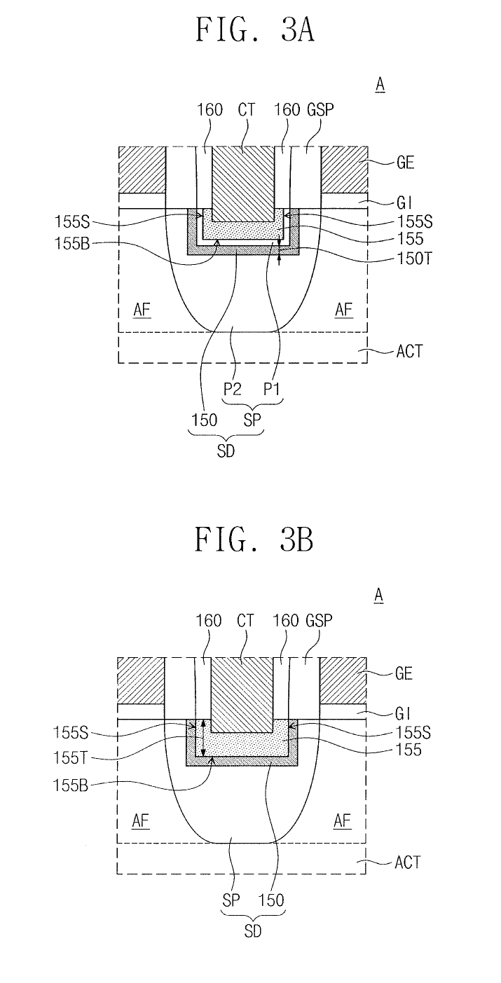

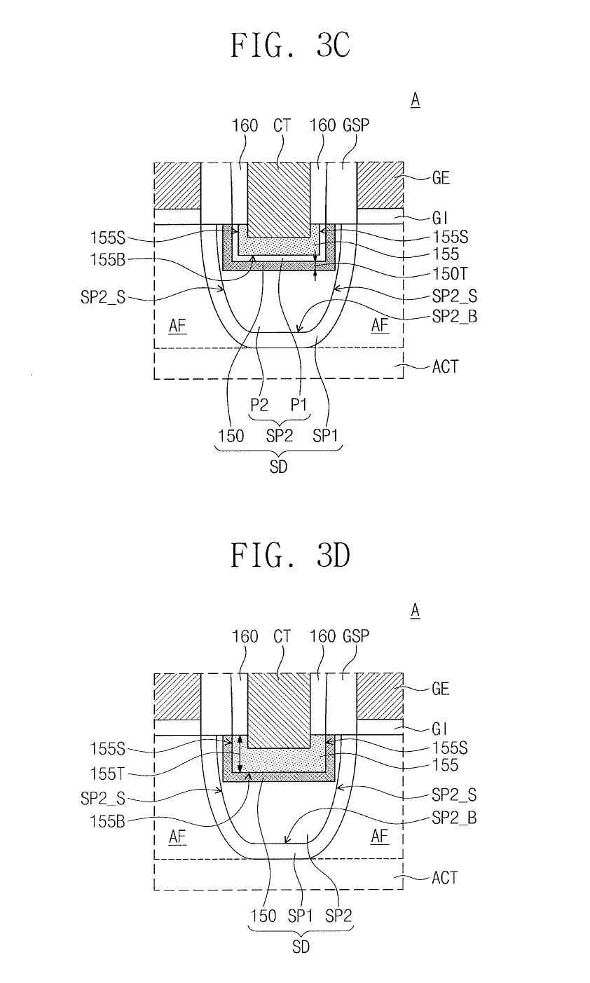

FIG. 1 illustrates a plan view showing a semiconductor device according to exemplary embodiments. FIG. 2 illustrates a cross-sectional view taken along lines I-I′ and II-IF of FIG. 1. FIG. 3 illustrates an enlarged view showing section A of FIG. 2.

Referring to FIGS. 1 and 2, an active pattern ACT may be provided on a substrate 100. The active pattern ACT may protrude from the substrate 100 along a direction perpendicular to a bottom surface 100B of the substrate 100. The active pattern ACT may extend in or along a first direction D1 parallel to the bottom surface 100B of the substrate 100. The substrate 100 may be a silicon substrate, a germanium substrate, or a silicon-on-insulator (SOI) substrate. The active pattern ACT may include the same material as that of the substrate 100.

The substrate 100 may be provided thereon with device isolation patterns ST on opposite sides of the active pattern ACT. The device isolation patterns ST may extend in the first direction D1, and may be spaced apart from each other in a second direction D2 intersecting the first direction D1. The second direction D2 may be parallel to the bottom surface 100B of the substrate 100. The device isolation patterns ST may be spaced apart in the second direction D2 from each other with the active pattern ACT therebetween. The device isolation patterns ST may include, e.g., an oxide, nitride, or oxynitride. The device isolation patterns ST may expose (e.g., may not cover or contact) an upper portion of the active pattern ACT. An active fin AF may be defined to indicate the upper portion of the active pattern ACT, which is exposed by the device isolation patterns ST. The active fin AF may be an active region shaped like a fin. Each of the device isolation patterns ST may have a top surface ST_U at a height from the substrate 100 (e.g., from the bottom surface 100B) that is lower or smaller than that of an uppermost surface AF_U of the active fin AF. The uppermost surface AF_U of the active fin AF may correspond to an uppermost surface of the active pattern ACT. The device isolation patterns ST may expose side surfaces of the active fin AF.

The substrate 100 may be provided thereon with a gate structure GS running across (e.g., crossing) the active pattern ACT. The gate structure GS may extend in the second direction D2 and run across the device isolation patterns ST. In an implementation, a plurality of gate structures GS may be provided to run across the active pattern ACT. In this case, the plurality of gate structures GS may be spaced apart from each other in the first direction D1. Each of the plurality of gate structures GS may extend in the second direction D2 and run across the device isolation patterns ST.

The gate structure GS may cover the uppermost surface AF_U and the exposed side surfaces of the active fin AF. The gate structure GS may extend in the second direction D2 and cover the top surface ST_U of each of the device isolation patterns ST.

The gate structure GS may include a gate electrode GE covering the active fin AF, a gate dielectric pattern GI between the gate electrode GE and the active fin AF, a gate capping pattern CAP on a top surface of the gate electrode GE, and gate spacers GSP on side surfaces of the gate electrode GE. The gate electrode GE may run across the active pattern ACT and the device isolation patterns ST. The gate dielectric pattern GI may extend along a bottom surface of the gate electrode GE. The gate dielectric pattern GI may be interposed between the gate electrode GE and the uppermost surface AF_U of the active fin AF and between the gate electrode GE and the exposed side surfaces of the active fin AF, and may extend between the gate electrode GE and the top surface ST_U of each of the device isolation patterns ST. The gate capping pattern CAP may extend in the second direction D2 along the top surface of the gate electrode GE. Each of the gate spacers GSP may extend in the second direction D2 along a corresponding one of the side surfaces of the gate electrode GE.

The gate electrode GE may include a conductive material. For example, the gate electrode GE may include one or more of a doped semiconductor material, conductive metal nitride (e.g., titanium nitride or tantalum nitride), and metal (e.g., aluminum or tungsten). The gate dielectric pattern GI may include at least one of high-k dielectric layers. For example, the gate dielectric pattern GI may include one or more of hafnium oxide, hafnium silicate, zirconium oxide, and zirconium silicate. The gate capping pattern CAP and the gate spacers GSP may include nitride (e.g., silicon nitride).

Source/drain patterns SD may be provided on the active pattern ACT at opposite sides of the gate structure GS. The active fin AF may be locally provided below the gate structure GS and interposed between the source/drain patterns SD. The source/drain patterns SD may be spaced apart from each other in a horizontal direction (e.g., in the first direction D1) with the active fin AF therebetween. Each of the source/drain patterns SD may have a lowermost surface SD_L at a height from the substrate 100 (e.g., the bottom surface 100B) that is lower or smaller than the height of the uppermost surface AF_U of the active fin AF. The gate structure GS and the source/drain patterns SD may constitute a transistor, and the active fin AF may be used as a channel of the transistor.

Referring to FIGS. 2 and 3A, each of the source/drain patterns SD may include a semiconductor pattern SP. When the transistor is an NMOSFET, the source/drain patterns SD may be configured to provide a tensile strain to a channel region (i.e., the active fin AF) of the NMOSFET. In this case, the semiconductor pattern SP may include silicon (Si) or silicon carbide (SiC). When the transistor is a PMOSFET, the source/drain patterns SD may be configured to provide a compressive strain to a channel region (i.e., the active fin AF) of the PMOSFET. In this case, the semiconductor pattern SP may include silicon germanium (SiGe). Each of the source/drain patterns SD may further include impurities doped in the semiconductor pattern SP. The impurities may be introduced to improve electrical characteristics of the transistor. When the transistor is an NMOSFET, the impurities may be N-type impurities (e.g., phosphorous (P) or arsenic (As)). When the transistor is a PMOSFET, the impurities may be P-type impurities (e.g., boron (B)).

Each of the source/drain patterns SD may further include a barrier layer 150. In an implementation, the barrier layer 150 may divide the semiconductor pattern SP into a first segment P1 and a second segment P2. The second segment P2 may be interposed between the first segment P1 and the active pattern ACT and between the first segment P1 and the active fin AF. The barrier layer 150 may be interposed between the first segment P1 and the second segment P2. When viewed in cross-section, the barrier layer 150 may have a roughly U shape (e.g., a |_| shape). The semiconductor pattern SP may be configured in such a way that the first segment P1 has an impurity concentration different from that of the second segment P2. The barrier layer 150 may include an oxygen atom (e.g., may include oxygen). The barrier layer 150 may further include the same element as that of the semiconductor pattern SP. For example, the barrier layer 150 may include silicon oxide. The barrier layer 150 may have a thickness 150T that is less than its maximum thickness that allows the active pattern ACT and the active fin AF to serve as a seed for epitaxial growth of the semiconductor pattern SP.

The source/drain patterns SD may be provided thereon with corresponding conductive patterns 155. Each of the source/drain patterns SD may cover a bottom surface 155B and side surfaces 155S of the conductive pattern 155. For example, each of the conductive patterns 155 may be provided on the first segment P1 of the semiconductor pattern SP. The first segment P1 may cover the bottom surface 155B and the side surfaces 155S of the conductive pattern 155. The barrier layer 150 may be adjacent to the conductive pattern 155, and may extend along or in parallel with the bottom surface 155B and the side surfaces 155S of the conductive pattern 155. The barrier layer 150 may be interposed between the conductive pattern 155 and the second segment P2 of the semiconductor pattern SP, and the first segment P1 of the semiconductor pattern SP may be interposed between the barrier layer 150 and the conductive pattern 155. The conductive patterns 155 may include a metal-semiconductor compound. For example, the conductive patterns 155 may include metal silicide. The metal silicide may include one or more of titanium, nickel, cobalt, tungsten, tantalum, platinum, palladium, and erbium.

Referring back to FIGS. 1 and 2, the substrate 100 may be provided thereon with an interlayer dielectric layer 160 covering the gate structure GS, the source/drain patterns SD, and the conductive patterns 155. The interlayer dielectric layer 160 may include one or more of a silicon oxide layer, a silicon nitride layer, a silicon oxynitride layer, and a low-k dielectric layer.

The interlayer dielectric layer 160 may be provided therein with contact plugs CT connected to corresponding conductive patterns 155. Each of the conductive patterns 155 may be interposed between a corresponding one of the contact plugs CT and a corresponding one of the source/drain patterns SD. The conductive patterns 155 may be used for ohmic contacts between the contact plugs CT and the source/drain patterns SD. Each of the contact plugs CT may be connected through a corresponding one of the conductive patterns 155 to a corresponding one of the source/drain patterns SD. The contact plugs CT may include a conductive material (e.g., metal).

A gate contact may partially penetrate the interlayer dielectric layer 160 to come into connection with the gate electrode GE. The interlayer dielectric layer 160 may be provided thereon with wiring lines connected to the contact plugs CT and the gate contact. The gate contact and the wiring lines may include a conductive material (e.g., metal). Source/drain voltages may be applied to the source/drain patterns SD through the contact plugs CT and the wiring lines connected to the contact plugs CT, and a gate voltage may be applied to the gate electrode GE through the gate contact and the wiring lines connected to the gate contact.

In order to decrease Schottky barrier heights between contact plugs and source/drain patterns, impurities may be implanted into an upper portion of the semiconductor pattern adjacent to the conductive pattern. The conductive patterns may be formed by a heat treatment process, and the heat treatment process may diffuse the impurities from the upper portion of the semiconductor pattern into neighboring patterns. If the impurities were to diffuse into an active pattern and an active fin, a short channel effect may deteriorate electrical characteristics of the transistor.

According to an embodiment, each of the source/drain patterns SD may include the barrier layer 150 adjacent to the conductive pattern 155. Each of the conductive patterns 155 may be provided in or on the first segment P1 of the semiconductor pattern SP, and the barrier layer 150 may be interposed between the first and second segments P1 and P2 of the semiconductor pattern SP. The barrier layer 150 may help minimize or prevent the impurities from diffusing into neighboring patterns from the first segment P1 of the semiconductor pattern SP. It thus may be possible to advantageously reduce the Schottky barrier heights between the contact plugs CT and the source/drain patterns SD and simultaneously to minimize deterioration of the transistor due to the short channel effect. As a result, the transistor may improve in electrical characteristics.

FIGS. 3B, 3C, and 3D illustrate enlarged views showing section A of FIG. 2, according to some embodiments. For brevity of explanation, the following description will focus on differences from the semiconductor device discussed with reference to FIGS. 1, 2, and 3A.

Referring to FIGS. 2 and 3B, each of the source/drain patterns SD may include the semiconductor pattern SP and the barrier layer 150. In an implementation, the semiconductor pattern SP and the barrier layer 150 may be sequentially stacked on the active pattern ACT. The semiconductor pattern SP may be interposed between the barrier layer 150 and the active pattern ACT and between the barrier layer 150 and the active fin AF. Each of the source/drain patterns SD may further include impurities doped in the semiconductor pattern SP.

The conductive patterns 155 may be provided on corresponding source/drain patterns SD. Each of the source/drain patterns SD may cover the bottom surface 155B and the side surfaces 155S of the conductive pattern 155. For example, the barrier layer 150 may cover the bottom surface 155B and the side surfaces 155S of the conductive pattern 155, and may be interposed between the semiconductor pattern SP and the conductive pattern 155. When viewed in cross-section, the barrier layer 150 may have a U shape. For example, the barrier layer 150 may be in direct contact with the bottom surface 155B and the side surfaces 155S of the conductive pattern 155.

In order to reduce resistance of contact plugs, a heat treatment process for forming conductive patterns may be performed at a relatively high temperature to increase a thickness of each of the conductive patterns. In this case, the thickness of each of the conductive patterns may have a non-uniform distribution, and as a result, the transistor may deteriorate in characteristics such as leakage current.

According to an embodiment, the barrier layer 150 may stop the formation of the conductive patterns 155 during the heat treatment process. For example, each of the conductive patterns 155 may be formed to contact the barrier layer 150, and each of the conductive patterns 155 may then have a uniform distribution of the thickness 155T. It thus may be possible to minimize the deterioration of the transistor. As a result, the transistor may improve in electrical characteristics.

Referring to FIGS. 2 and 3C, each of the source/drain patterns SD may include a first semiconductor pattern SP1 and a second semiconductor pattern SP2 that are sequentially stacked on the active pattern ACT. The first semiconductor pattern SP1 may be interposed between the second semiconductor pattern SP2 and the active pattern ACT, and may extend between the second semiconductor pattern SP2 and the active fin AF. The first semiconductor pattern SP1 may cover a bottom surface SP2_B and side surfaces SP2_S of the second semiconductor pattern SP2. When viewed in cross-section, the first semiconductor pattern SP1 may have a U shape. The first semiconductor pattern SP1 may include a material having a lattice constant that is different from that of the second semiconductor pattern SP2. Each of the source/drain patterns SD may further include impurities doped in each of the first and second semiconductor patterns SP1 and SP2. The first semiconductor pattern SP1 may have an impurity concentration different from that of the second semiconductor pattern SP2.

Each of the source/drain patterns SD may further include the barrier layer 150. In an implementation, the barrier layer 150 may divide the second semiconductor pattern SP2 into a first segment P1 and a second segment P2. The second segment P2 may be interposed between the first segment P1 and the first semiconductor pattern SP1. The barrier layer 150 may be interposed between the first segment P1 and the second segment P2. When viewed in cross-section, the barrier layer 150 may have a U shape. The second semiconductor pattern SP2 may be configured in such a way that the first segment P1 has an impurity concentration that is different from that of the second segment P2. The barrier layer 150 may include an oxygen atom. The barrier layer 150 may further include the same element as those of the first and second semiconductor patterns SP1 and SP2. For example, the barrier layer 150 may include silicon oxide. The barrier layer 150 may have a thickness 150T that is less than its maximum thickness that allows the active pattern ACT and the active fin AF to serve as a seed for epitaxial growth of the first and second semiconductor patterns SP1 and SP2.

The conductive patterns 155 may be provided on corresponding source/drain patterns SD. Each of the source/drain patterns SD may cover the bottom surface 155B and the side surfaces 155S of the conductive pattern 155. For example, each of the conductive patterns 155 may be provided in the first segment P1 of the second semiconductor pattern SP2. The first segment P1 may cover the bottom surface 155B and the side surfaces 155S of the conductive pattern 155. The barrier layer 150 may be adjacent to the conductive pattern 155, and may extend along the bottom surface 155B and the side surfaces 155S of the conductive pattern 155. The barrier layer 150 may be interposed between the second segment P2 of the second semiconductor pattern SP2 and the conductive pattern 155, and the first segment P1 of the second semiconductor pattern SP2 may be interposed between the barrier layer 150 and the conductive pattern 155.

In an implementation, each of the source/drain patterns SD may include the barrier layer 150 adjacent to the conductive pattern 155. Each of the conductive patterns 155 may be provided on the first segment P1 of the second semiconductor pattern SP2, and the barrier layer 150 may be interposed between the first and second segments P1 and P2 of the second semiconductor pattern SP2. The barrier layer 150 may help minimize or prevent the impurities from diffusing into neighboring patterns from the first segment P1 of the second semiconductor pattern SP2.

Referring to FIGS. 2 and 3D, as discussed with reference to FIGS. 2 and 3C, each of the source/drain patterns SD may include the first semiconductor pattern SP1 and the second semiconductor pattern SP2 that are sequentially stacked on the active pattern ACT. Each of the source/drain patterns SD may further include the barrier layer 150 and the impurities doped in each of the first and second semiconductor patterns SP1 and SP2.

In an implementation, the first semiconductor pattern SP1, the second semiconductor pattern SP2, and the barrier layer 150 may be sequentially stacked on the active pattern ACT. The first semiconductor pattern SP1 may be interposed between the second semiconductor pattern SP2 and the active pattern ACT and between the second semiconductor pattern SP2 and the active fin AF. The first semiconductor pattern SP1 may cover the bottom surface SP2_B and the side surfaces SP2_S of the second semiconductor pattern SP2. When viewed in cross-section, the first semiconductor pattern SP1 may have a U shape. The second semiconductor pattern SP2 may be interposed between the barrier layer 150 and the first semiconductor pattern SP1.

The conductive patterns 155 may be provided on corresponding source/drain patterns SD. Each of the source/drain patterns SD may cover the bottom surface 155B and the side surfaces 155S of the conductive pattern 155. For example, the barrier layer 150 may cover the bottom surface 155B and the side surfaces 155S of the conductive pattern 155, and may be interposed between the conductive pattern 155 and the second semiconductor pattern SP2. When viewed in cross-section, the barrier layer 150 may have a U shape. The barrier layer 150 may be in direct contact with the bottom surface 155B and the side surfaces 155S of the conductive pattern 155.

In an implementation, each of the conductive patterns 155 may be formed to contact the barrier layer 150, and each of the conductive patterns 155 may then have a uniform distribution of the thickness 155T.

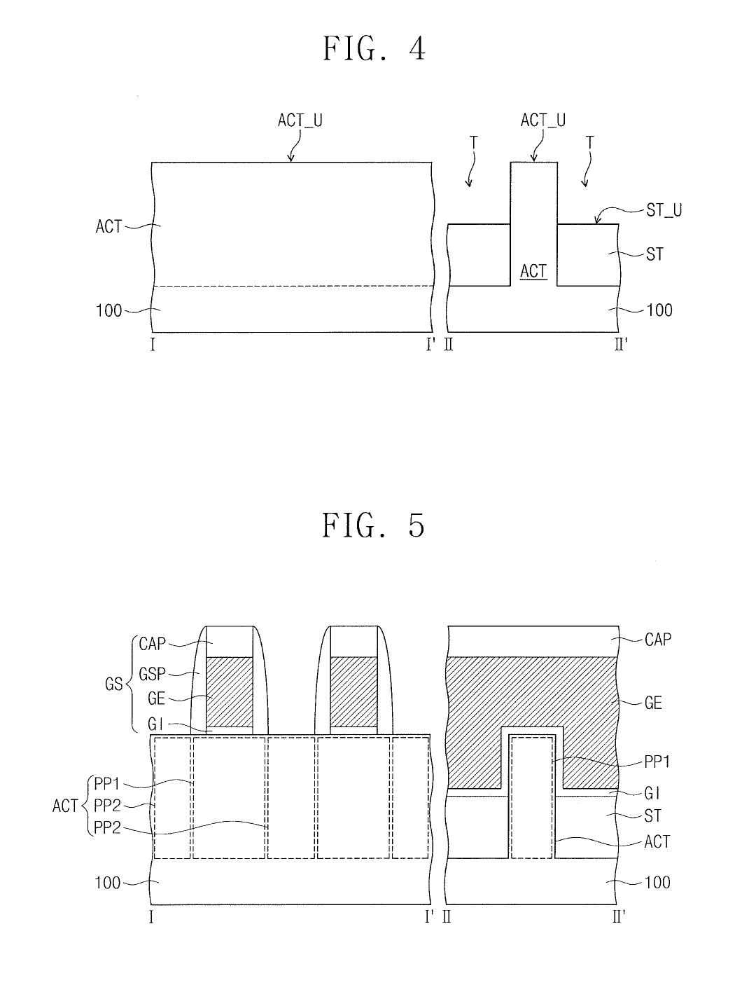

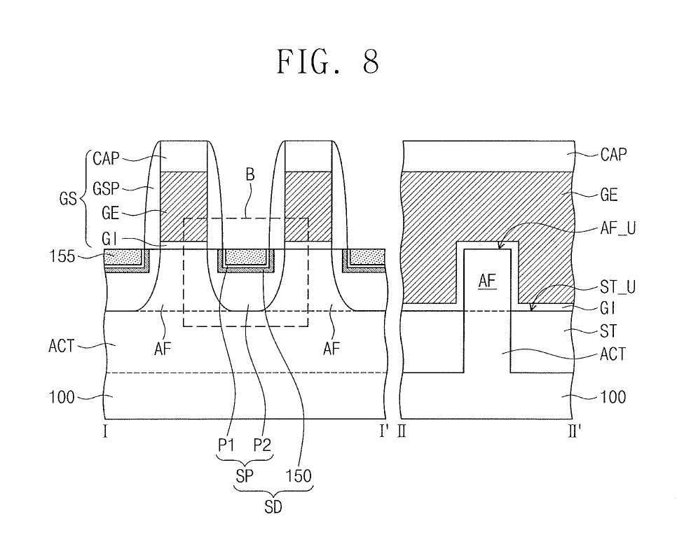

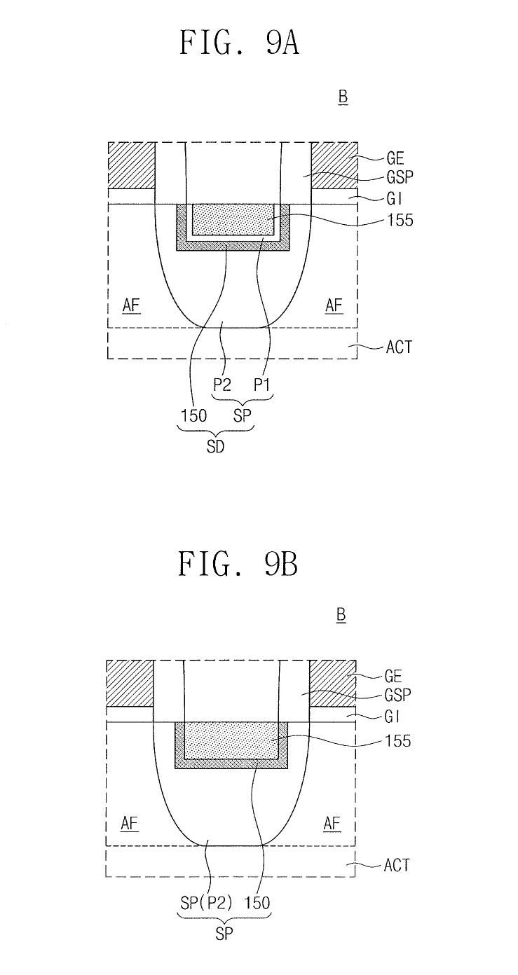

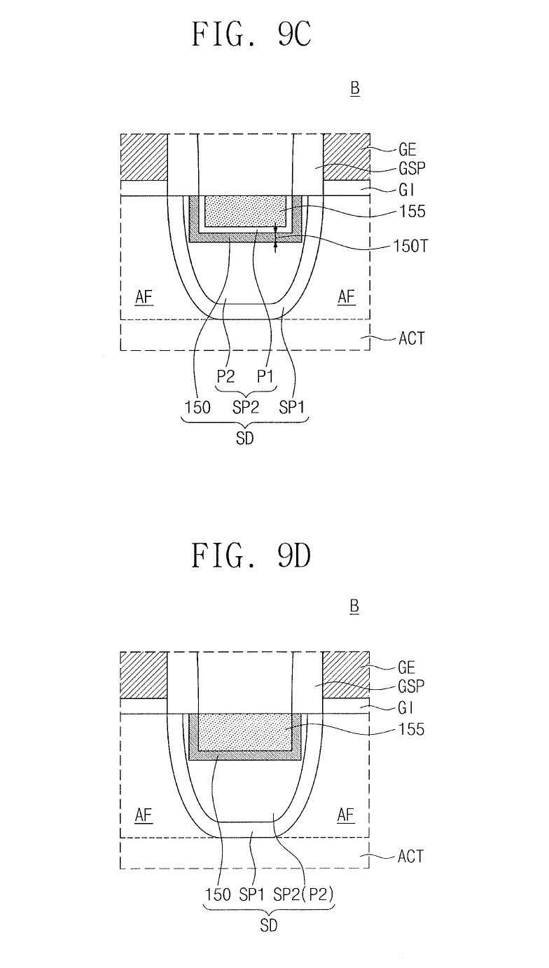

FIGS. 4 to 8 illustrate cross-sectional views taken along lines I-I′ and II-II′ of FIG. 1, showing stages in a method of manufacturing a semiconductor device according to exemplary embodiments. FIG. 9A illustrates an enlarged view showing section B of FIG. 8.

Referring to FIGS. 1 and 4, an upper portion of a substrate 100 may be patterned to form trenches T defining an active pattern ACT. The active pattern ACT may extend in a first direction D1. Each of the trenches T may have a linear shape extending in the first direction D1. The trenches T may be spaced apart in a second direction D2 from each other with the active pattern ACT interposed therebetween. The formation of the trenches T may include forming a mask pattern on the substrate 100 defining an area where the active pattern ACT is formed, and anisotropically etching the upper portion of the substrate 100 using the mask pattern as an etching mask.

Device isolation patterns ST may be formed on opposite sides of the active pattern ACT. The device isolation patterns ST may be formed in corresponding trenches T. The formation of the device isolation patterns ST may include forming an insulation layer filling the trenches T on the substrate 100 and performing a planarization process on the insulation layer until the mask pattern is exposed. An upper portion of each of the device isolation patterns ST may be recessed to expose an upper portion of the active pattern ACT. Each of the device isolation patterns ST may then have a top surface ST_U at a height from the substrate 100 that is lower than that of an uppermost surface ACT_U of the active pattern ACT. The mask pattern may be removed when the upper portion of each of the device isolation patterns ST is recessed.

Referring to FIGS. 1 and 5, a gate structure GS may be formed on the substrate 100, running across the active pattern ACT. The gate structure GS may extend in the second direction D2 and run across the device isolation patterns ST. The gate structure GS may include a gate dielectric pattern GI, a gate electrode GE, and a gate capping pattern CAP that are sequentially stacked on the substrate 100. The gate structure GS may further include gate spacers GSP on side surfaces of the gate electrode GE.

The formation of the gate structure GS may include forming a gate dielectric layer on the substrate 100 to cover the active pattern ACT and the device isolation patterns ST, forming a gate electrode layer on the gate dielectric layer, forming the gate capping pattern CAP on the gate electrode layer, and using the gate capping pattern CAP as an etching mask to sequentially etch the gate electrode layer and the gate dielectric layer. The gate electrode layer and the gate dielectric layer may be etched to respectively form the gate electrode GE and the gate dielectric pattern GI. The formation of the gate structure GS may further include forming a spacer layer on the substrate 100 to conformally cover the gate dielectric pattern GI, the gate electrode GE, and the gate capping pattern CAP, and anisotropically etching the spacer layer to form the gate spacers GSP.

The gate structure GS may be formed to run across the active pattern ACT, and the active pattern ACT may include a first portion PP1 and second portions PP2. The first portion PP1 may be positioned below the gate structure GS and may correspond to a portion of the active pattern ACT, which overlaps the gate structure GS when viewed in plan. The second portions PP2 may correspond to other portions of the active pattern ACT that are positioned at opposite sides of the gate structure GS when viewed in plan.

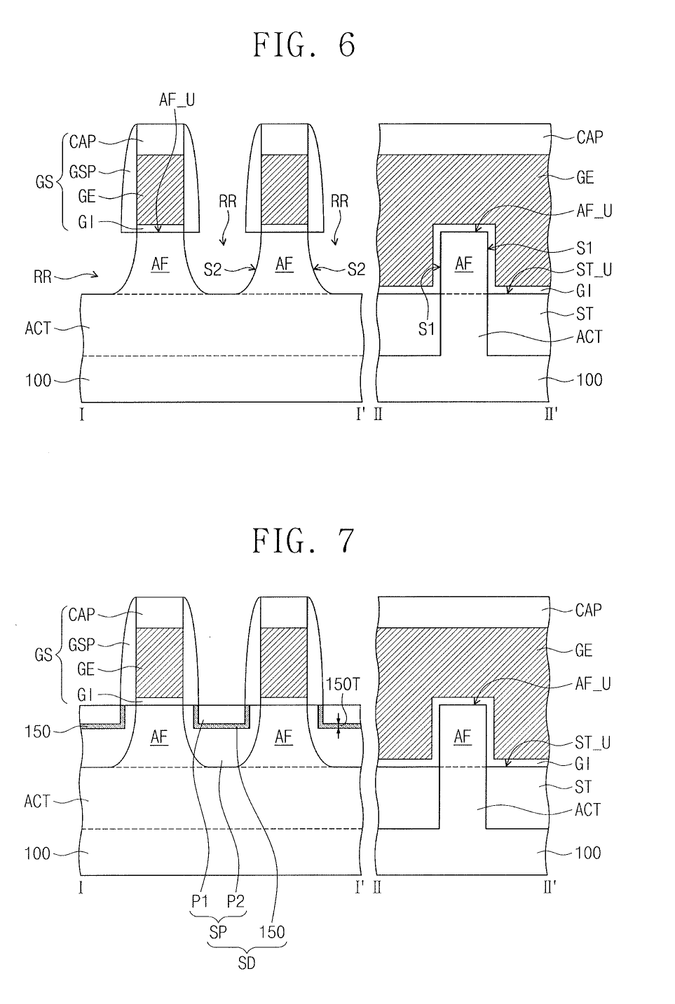

Referring to FIGS. 1 and 6, upper portions of the second portions PP2 of the active pattern ACT may be recessed to form recess regions RR. The first portion PP1 of the active pattern ACT may have an upper portion (referred to hereinafter as an active fin AF) that includes first side surfaces S1 exposed by the device isolation patterns ST and second side surfaces S2 exposed to the recess regions RR. The active fin AF may have an uppermost surface AF_U corresponding to the uppermost surface ACT_U of the active pattern ACT. The gate structure GS may cover the uppermost surface AF_U and the first side surfaces S1 of the active fin AF.

The formation of the recess regions RR may include performing, e.g., a dry or wet etching process to etch the upper portions of the second portions PP2 of the active pattern ACT. In an implementation, the recess regions RR may extend below the gate spacers GSP.

Referring to FIGS. 1 and 7, source/drain patterns SD may be formed on the active pattern ACT at opposite sides of the gate structure GS. The source/drain patterns SD may be formed in corresponding recess regions RR. The formation of the source/drain patterns SD may include forming a semiconductor pattern SP by performing a selective epitaxial growth process in which the active pattern ACT and the active fin AF are used as a seed layer, and doping impurities into the semiconductor pattern SP during or after the selective epitaxial growth process. The semiconductor pattern SP may include, e.g., silicon (Si), silicon carbide (SiC), or silicon germanium (SiGe), and the impurities may include N-type impurities (e.g., phosphorous (P) or arsenic (As)) or P-type impurities (e.g., boron (B)).

The formation of the source/drain patterns SD may further include forming a barrier layer 150 in the semiconductor pattern SP by injecting oxygen during the selective epitaxial growth process. The barrier layer 150 may have a thickness 150T that is less than its maximum thickness of the barrier layer 150 that allows the active pattern ACT and the active fin AF to serve as a seed for epitaxial growth of the semiconductor pattern SP. If the thickness 150T were greater than the maximum thickness of the barrier layer 150, it could be difficult to use the active pattern ACT and the active fin AF as a seed for epitaxial growth of the semiconductor pattern SP. The barrier layer 150 may further include the same element as that of the semiconductor pattern SP. For example, the barrier layer 150 may include silicon oxide. The barrier layer 150 may divide the semiconductor pattern SP into a first segment P1 and a second segment P2. The second segment P2 may be interposed between the first segment P1 and the active pattern ACT and between the first segment P1 and the active fin AF. The barrier layer 150 may be formed to lie between the first segment P1 and the second segment P2.

Referring to FIGS. 1, 8, and 9A, conductive patterns 155 may be formed on corresponding source/drain patterns SD. Each of the conductive patterns 155 may be formed on or in the first segment P1 of the semiconductor pattern SP. The formation of the conductive patterns 155 may include depositing a metal layer on the substrate 100 on which the source/drain patterns SD are formed, performing a heat treatment process to react the metal layer with the first segment P1 of the semiconductor pattern SP, and removing the metal layer. The metal layer may be formed to cover a top surface of the first segment P1 of the semiconductor pattern SP. Each of the conductive patterns 155 may be formed when the heat treatment process causes a portion of the first segment P1 to react with the metal layer. When the metal layer has a remaining portion that does not react with the first segment P1, the remaining portion of the metal layer may be removed after the conductive patterns 155 are formed.

Referring back to FIGS. 1 and 2, an interlayer dielectric layer 160 may be formed on the substrate 100 on which the conductive patterns 155 are formed. The interlayer dielectric layer 160 may be formed to cover the gate structure GS, the source/drain patterns SD, and the conductive patterns 155. Contact plugs CT may be formed in the interlayer dielectric layer 160 to come into connection with corresponding conductive patterns 155. The formation of the contact plugs CT may include forming contact holes that penetrate the interlayer dielectric layer 160 and expose corresponding conductive patterns 155, and forming the contact plugs CT in corresponding contact holes. A gate contact may be formed in the interlayer dielectric layer 160 to come into connection with the gate electrode GE. The formation of the gate contact may include forming a gate contact hole that partially penetrates the interlayer dielectric layer 160 and exposes the gate electrode GE, and forming the gate contact in the gate contact hole. Wiring lines may be formed on the interlayer dielectric layer 160 to come into connection with the contact plugs CT and the gate contact. The wiring lines may be configured to apply voltages to the source/drain patterns SD and the gate electrode GE through the contact plugs CT and the gate contact.

FIGS. 9B to 9D illustrate enlarged views showing section B of FIG. 8, showing a method of manufacturing a semiconductor device according to exemplary embodiments. For brevity of description, the following description will focus on differences from the method of manufacturing a semiconductor device according to some embodiments discussed with reference to FIGS. 1, 4 to 8, and 9A.

Referring to FIGS. 8 and 9B, each of the conductive patterns 155 may be formed to contact the barrier layer 150. First, as discussed with reference to FIG. 7, the source/drain patterns SD may be formed to include the semiconductor pattern SP and the barrier layer 150. The barrier layer 150 may divide the semiconductor pattern SP into the first segment P1 and the second segment P2. The formation of the conductive patterns 155 may include depositing a metal layer on the substrate 100 on which the source/drain patterns SD are formed, performing a heat treatment process to react the metal layer with the first segment P1 of the semiconductor pattern SP, and removing the metal layer. In an implementation, each of the conductive patterns 155 may be formed when the heat treatment process causes a whole portion, e.g., all, of the first segment P1 to react with the metal layer. In this case, the barrier layer 150 may function to stop the formation of the conductive patterns 155 during the heat treatment process. When the metal layer has a remaining portion that does not react with the first segment P1, the remaining portion of the metal layer may be removed after the conductive patterns 155 are formed.

Referring to FIGS. 8 and 9C, the formation of the source/drain patterns SD may include sequentially forming a first semiconductor pattern SP1 and a second semiconductor pattern SP2 by performing a selective epitaxial growth process in which the active pattern ACT and the active fin AF are used as a seed, and doping impurities into each of the first and second semiconductor patterns SP1 and SP2 during or after the selective epitaxial growth process. The first and second semiconductor patterns SP1 and SP2 may be formed to sequentially cover an inner surface of each of the recess regions RR. Each of the first and second semiconductor patterns SP1 and SP2 may include, e.g., silicon (Si), silicon carbide (SiC), or silicon germanium (SiGe).

In an implementation, the formation of the source/drain patterns SD may further include forming the barrier layer 150 in the second semiconductor pattern SP2 by injecting oxygen during the selective epitaxial growth process. The barrier layer 150 may have a thickness 150T that is less than its maximum thickness that allows the active pattern ACT and the active fin AF to serve as a seed for epitaxial growth of the first and second semiconductor patterns SP1 and SP2. If the thickness 150T were to be greater than the maximum thickness of the barrier layer 150, it could be difficult to use the active pattern ACT and the active fin AF as a seed for epitaxial growth of the first and second semiconductor patterns SP1 and SP2. The barrier layer 150 may further include the same element as those of the first and second semiconductor patterns SP1 and SP2. For example, the barrier layer 150 may include silicon oxide. The barrier layer 150 may divide the second semiconductor pattern SP2 into a first segment P1 and a second segment P2. The second segment P2 may be interposed between the first segment P1 and the first semiconductor pattern SP1. The barrier layer 150 may be formed to lie between the first segment P1 and the second segment P2.

In an implementation, each of the conductive patterns 155 may be formed in the first segment P1 of the second semiconductor pattern SP2. The formation of the conductive patterns 155 may include depositing a metal layer on the substrate 100 on which the source/drain patterns SD are formed, performing a heat treatment process to react the metal layer with the first segment P1 of the second semiconductor pattern SP2, and removing the metal layer. The metal layer may be formed to cover a top surface of the first segment P1 of the second semiconductor pattern SP2. Each of the conductive patterns 155 may be formed when the heat treatment process causes a portion of the first segment P1 to react with the metal layer. When the metal layer has a remaining portion that does not react with the first segment P1, the remaining portion of the metal layer may be removed after the conductive patterns 155 are formed.

Referring to FIGS. 8 and 9D, the source/drain patterns SD may be formed by substantially the same method as that discussed with reference to FIGS. 8 and 9C. The source/drain patterns SD may be formed to include the first and second semiconductor patterns SP1 and SP2 and the barrier layer 150. The barrier layer 150 may divide the second semiconductor pattern SP2 into the first segment P1 and the second segment P2. Each of the conductive patterns 155 may be formed to contact the barrier layer 150. The formation of the conductive patterns 155 may include depositing a metal layer on the substrate 100 on which the source/drain patterns SD are formed, performing a heat treatment process to react the metal layer with the first segment P1 of the second semiconductor pattern SP2, and removing the metal layer. In an implementation, each of the conductive patterns 155 may be formed when the heat treatment process causes the entire first segment P1 to react with the metal layer. In this case, the barrier layer 150 may stop the formation of the conductive patterns 155 during the heat treatment process. When the metal layer has a remaining portion that does not react with the first segment P1 of the second semiconductor pattern SP2, the remaining portion of the metal layer may be removed after the conductive patterns 155 are formed.

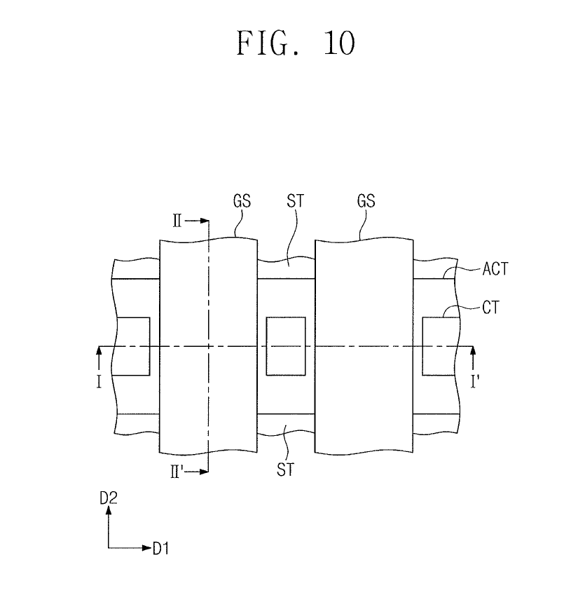

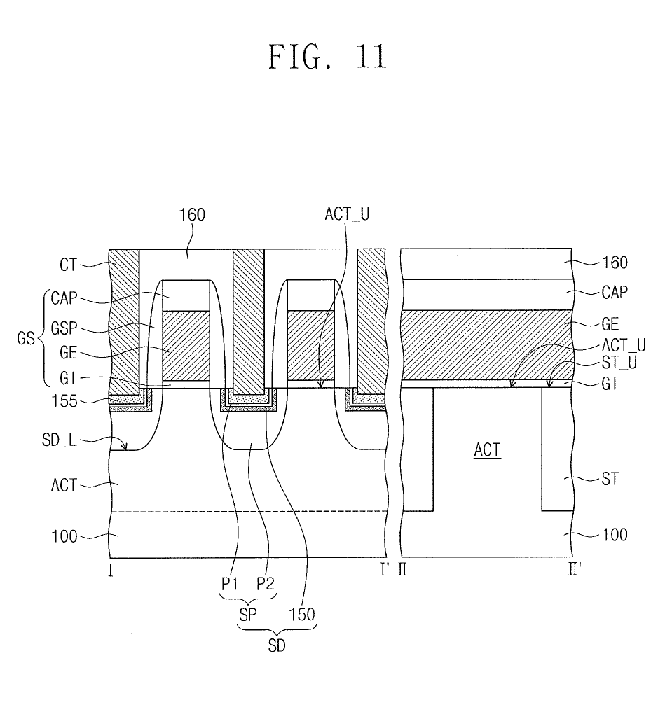

FIG. 10 illustrates a plan view showing a semiconductor device according to exemplary embodiments. FIG. 11 illustrates a cross-sectional view taken along lines I-I′ and II-II′ of FIG. 10. For brevity of explanation, the following description will focus on differences from the semiconductor device discussed with reference to FIGS. 1, 2, and 3A.

Referring to FIGS. 10 and 11, an active pattern ACT may be provided on a substrate 100. The active pattern ACT may protrude from the substrate 100 along a direction perpendicular to a bottom surface 100B of the substrate 100. The active pattern ACT may extend in a first direction D1 parallel to the bottom surface 100B of the substrate 100. The substrate 100 may be provided thereon on with device isolation patterns ST on opposite sides of the active pattern ACT. The device isolation patterns ST may extend in the first direction D1, and may be spaced apart from each other in a second direction D2 intersecting the first direction D1. The second direction D2 may be parallel to the bottom surface 100B of the substrate 100. The device isolation patterns ST may be spaced apart in the second direction D2 from each other with the active pattern ACT interposed therebetween. In an implementation, each of the device isolation patterns ST may have a top surface ST_U that is substantially coplanar with an uppermost surface ACT_U of the active pattern ACT. The top surface ST_U of each of the device isolation patterns ST may be at a height from the substrate 100 that is substantially the same as that of the uppermost surface ACT_U of the active pattern ACT.

A gate structure GS may be provided to cross the active pattern ACT and the device isolation patterns ST. The gate structure GS may cover the uppermost surface ACT_U of the active pattern ACT and the top surface ST_U of each of the device isolation patterns ST. The gate structure GS may include a gate electrode GE crossing the active pattern ACT and the device isolation patterns ST, a gate dielectric pattern GI between the gate electrode GE and the active pattern ACT, a gate capping pattern CAP on a top surface of the gate electrode GE, and gate spacers GSP on side surfaces of the gate electrode GE. The gate electrode GE may extend in the second direction D2, and cover the uppermost surface ACT_U of the active pattern ACT and the top surface ST_U of each of the device isolation patterns ST. The gate dielectric pattern GI may be interposed between the gate electrode GE and the uppermost surface ACT_U of the active pattern ACT, and may extend between the gate electrode GE and the top surface ST_U of each of the device isolation patterns ST. The gate capping pattern CAP may extend in the second direction D2 along the top surface of the gate electrode GE. Each of the gate spacers GSP may extend in the second direction D2 along a corresponding one of the side surfaces of the gate electrode GE.

Source/drain patterns SD may be provided on the active pattern ACT at opposite sides of the gate structure GS. At least a portion of each of the source/drain patterns SD may penetrate an upper portion of the active pattern ACT. A portion of the active pattern ACT may be provided below the gate structure GS and interposed between the source/drain patterns SD. The source/drain patterns SD may be spaced apart in a horizontal direction (e.g., in the first direction D1) from each other with the portion of the active pattern ACT interposed therebetween. Each of the source/drain patterns SD may have a lowermost surface SD_L at a height from the substrate 100 lower than that of the uppermost surface ACT_U of the active pattern ACT. The portion of the active pattern ACT may have an uppermost surface corresponding to the uppermost surface ACT_U of the active pattern ACT. The gate structure GS and the source/drain patterns SD may constitute a transistor, and the portion of the active pattern ACT may be used as a channel of the transistor.

The source/drain patterns SD may be provided thereon with corresponding conductive patterns 155. As discussed with reference to FIGS. 2 and 3A, each of the source/drain patterns SD may include a semiconductor pattern SP and a barrier layer 150. The barrier layer 150 may divide the semiconductor pattern SP into a first segment P1 and a second segment P2. Each of the source/drain patterns SD may further include impurities doped in the semiconductor pattern SP. Each of the conductive patterns 155 may be provided in the first segment P1 of the semiconductor pattern SP. In an implementation, the source/drain patterns SD and the conductive patterns 155 may be configured as discussed with reference to FIGS. 2 and 3B to 3D.

A semiconductor device according to the present embodiment may be substantially the same as that discussed with reference to FIGS. 1, 2, and 3A, except for the differences mentioned above.

FIGS. 12 to 16 illustrate cross-sectional views taken along lines I-I′ and II-II′ of FIG. 10, showing stages in a method of manufacturing a semiconductor device according to exemplary embodiments. For brevity of description, the following description will focus on differences from the method of manufacturing a semiconductor device according to some embodiments discussed with reference to FIGS. 1, 4 to 8, and 9A.

Referring to FIGS. 10 and 12, an upper portion of a substrate 100 may be patterned to form trenches T defining an active pattern ACT. The active pattern ACT may extend in a first direction D1. The trenches T may be spaced apart in a second direction D2 from each other with the active pattern ACT interposed therebetween. The formation of the trenches T may include forming a mask pattern on the substrate 100 defining an area where the active pattern ACT is formed, and anisotropically etching the upper portion of the substrate 100 using the mask pattern as an etching mask.

Device isolation patterns ST may be formed on opposite sides of the active pattern ACT. The device isolation patterns ST may be formed to fill corresponding trenches T. The formation of the device isolation patterns ST may include forming an insulation layer on the substrate 100 to fill the trenches T, and performing a planarization process on the insulation layer until the active pattern ACT is exposed. The mask pattern may be removed during the planarization process. Each of the device isolation patterns ST may then have a top surface ST_U that is substantially coplanar with an uppermost surface ACT_U of the active pattern ACT. The top surface ST_U of each of the device isolation patterns ST may be at a height from the substrate 100 that is substantially the same as that of the uppermost surface ACT_U of the active pattern ACT.

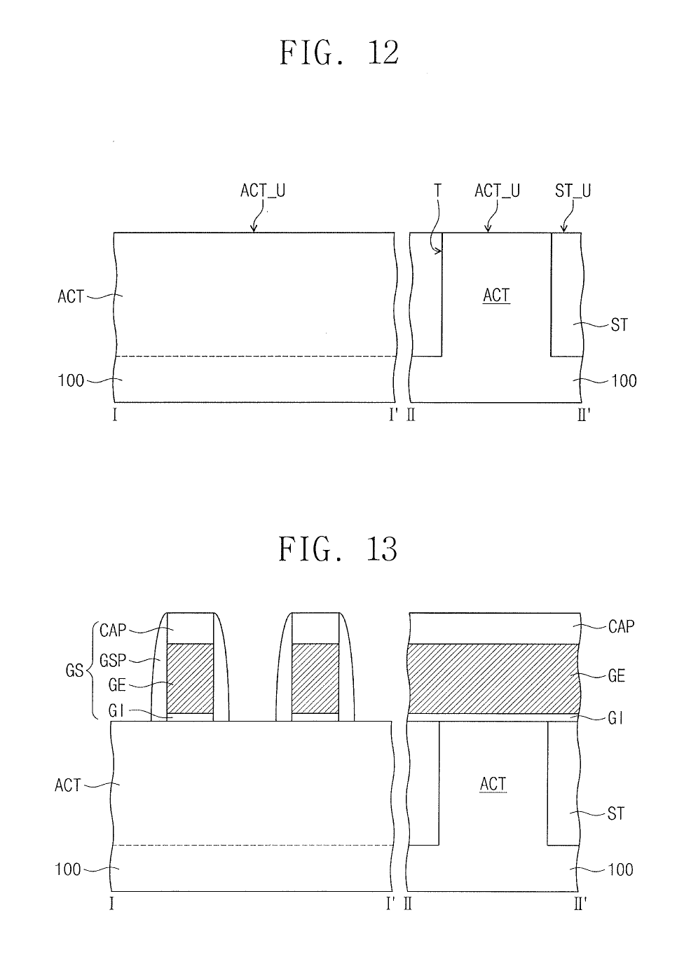

Referring to FIGS. 10 and 13, a gate structure GS may be formed on the substrate 100, crossing the active pattern ACT. The gate structure GS may extend in the second direction D2 and cross the device isolation patterns ST. The gate structure GS may include a gate dielectric pattern GI, a gate electrode GE, and a gate capping pattern CAP that are sequentially stacked on the substrate 100. The gate structure GS may further include gate spacers GSP on side surfaces of the gate electrode GE. The gate structure GS may be formed by substantially the same method as that discussed with reference to FIGS. 1 and 5.

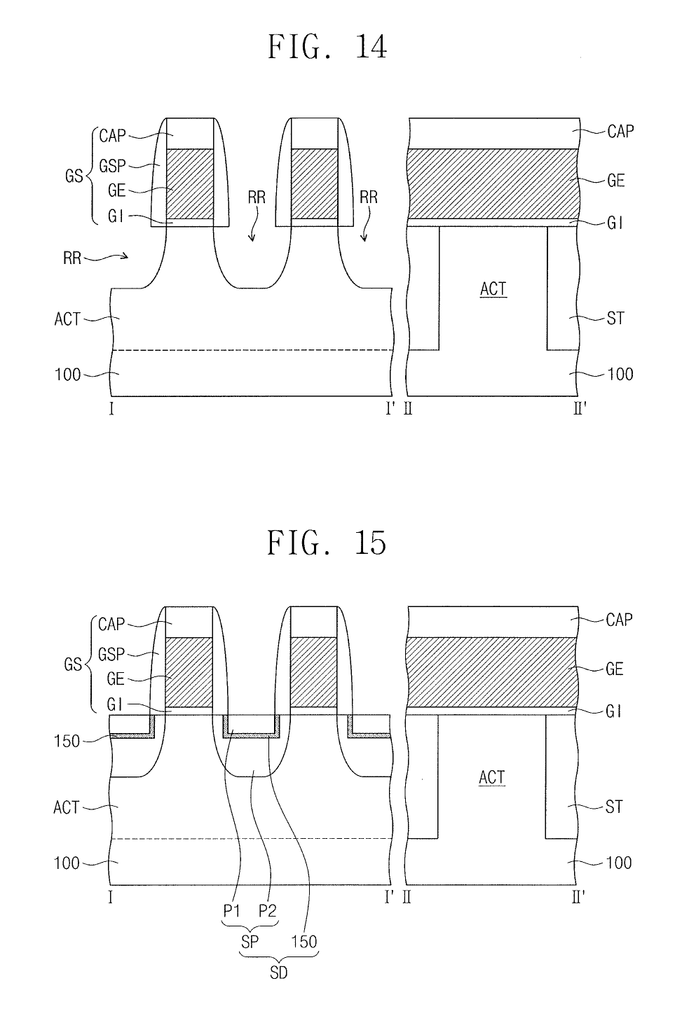

Referring to FIGS. 10 and 14, upper portions of the active pattern ACT at opposite sides of the gate structure GS may be recessed to form recess regions RR. The formation of the recess regions RR may include performing, e.g., a dry or wet etching process to etch the upper portions of the active pattern ACT. In some embodiments, the recess regions RR may extend below the gate spacers GSP.

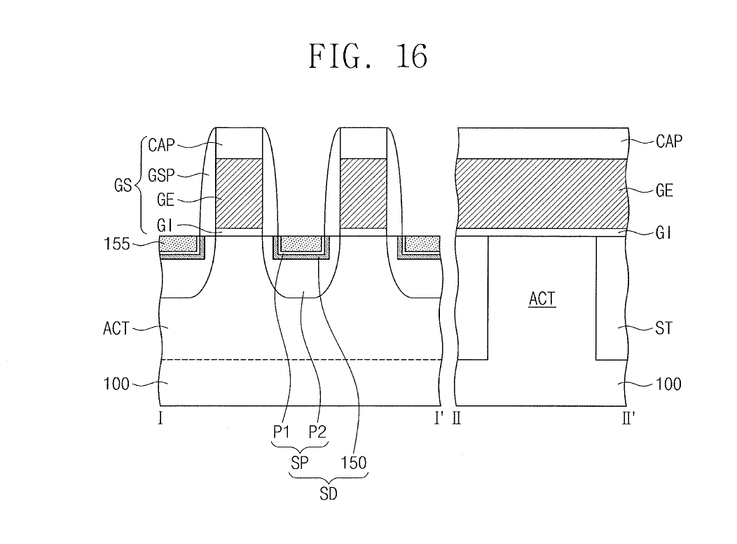

Referring to FIGS. 10 and 15, source/drain patterns SD may be formed on the active pattern ACT at opposite sides of the gate structure GS. The source/drain patterns SD may be formed in corresponding recess regions RR. Each of the source/drain patterns SD may include a semiconductor pattern SP and a barrier layer 150. The barrier layer 150 may divide the semiconductor pattern SP into a first segment P1 and a second segment P2. Each of the source/drain patterns SD may further include impurities doped in the semiconductor pattern SP. The source/drain patterns SD may be formed by substantially the same method as that discussed with reference to FIGS. 1 and 7.

Referring to FIGS. 10 and 16, conductive patterns 155 may be formed on corresponding source/drain patterns SD. Each of the conductive patterns 155 may be formed on the first segment P1 of the semiconductor pattern SP. The conductive patterns 155 may be formed by substantially the same method as that discussed with reference to FIGS. 1, 8, and 9A. In an implementation, the source/drain patterns SD and the conductive patterns 155 may be configured as discussed with reference to FIGS. 2 and 3B to 3D. In this case, the source/drain patterns SD and the conductive patterns 155 may be formed by substantially the same method as that discussed with reference to FIGS. 8 and 9B to 9D.

A method of manufacturing a semiconductor device according to the present embodiment may be substantially the same as that discussed with reference to FIGS. 1, 4 to 8, and 9A, except for the differences mentioned above.

According to an embodiment, each of the source/drain patterns SD may include the barrier layer 150 adjacent to (e.g., close to or in direct contact with) the conductive pattern 155. Each of the source/drain patterns SD may further include the semiconductor pattern SP and the impurities doped in the semiconductor pattern SP. When a portion of the semiconductor pattern SP or SP2 is interposed between the barrier layer 150 and the conductive pattern 155, the barrier layer 150 may help prevent the impurities from diffusing into neighboring patterns from the portion of the semiconductor pattern SP or SP2. It thus may be possible to reduce the Schottky barrier heights between the contact plugs CT and the source/drain patterns SD and simultaneously to minimize deterioration of the transistor due to the short channel effect.

Furthermore, when each of the conductive patterns 155 is formed to contact the barrier layer 150, the thickness 155T of each of the conductive patterns 155 may have a uniform distribution. The transistor may accordingly minimize its deterioration such as leakage current.

As a result, the transistor may improve in electrical characteristics.

As is traditional in the field, embodiments are described, and illustrated in the drawings, in terms of functional blocks, units and/or modules. Those skilled in the art will appreciate that these blocks, units and/or modules are physically implemented by electronic (or optical) circuits such as logic circuits, discrete components, microprocessors, hard-wired circuits, memory elements, wiring connections, and the like, which may be formed using semiconductor-based fabrication techniques or other manufacturing technologies. In the case of the blocks, units and/or modules being implemented by microprocessors or similar, they may be programmed using software (e.g., microcode) to perform various functions discussed herein and may optionally be driven by firmware and/or software. Alternatively, each block, unit and/or module may be implemented by dedicated hardware, or as a combination of dedicated hardware to perform some functions and a processor (e.g., one or more programmed microprocessors and associated circuitry) to perform other functions. Also, each block, unit and/or module of the embodiments may be physically separated into two or more interacting and discrete blocks, units and/or modules without departing from the scope herein. Further, the blocks, units and/or modules of the embodiments may be physically combined into more complex blocks, units and/or modules without departing from the scope herein.

By way of summation and review, as a size and design rule of the semiconductor device are gradually decreased, sizes of the MOSFETs may also be increasingly scaled down. The scale down of MOSFETs could deteriorate operating characteristics of the semiconductor device. A semiconductor device having excellent performance while overcoming limitations due to integration of the semiconductor device may be manufactured.

According to an embodiment, a source/drain pattern may include a barrier layer adjacent to a conductive pattern. The barrier layer may help minimize or suppress impurities from diffusing into neighboring patterns from the source/drain pattern. In addition, when the conductive pattern is formed to contact the barrier layer, the conductive pattern may reduce in thickness distribution. A transistor including the source/drain pattern may thus improve in electrical characteristics.

The embodiments may provide a semiconductor device including a field effect transistor.

The embodiments may provide a semiconductor device having improved electrical characteristics and a method of manufacturing the same.

Example embodiments have been disclosed herein, and although specific terms are employed, they are used and are to be interpreted in a generic and descriptive sense only and not for purpose of limitation. In some instances, as would be apparent to one of ordinary skill in the art as of the filing of the present application, features, characteristics, and/or elements described in connection with a particular embodiment may be used singly or in combination with features, characteristics, and/or elements described in connection with other embodiments unless otherwise specifically indicated. Accordingly, it will be understood by those of skill in the art that various changes in form and details may be made without departing from the spirit and scope of the present invention as set forth in the following claims.

What is claimed is:

1. A semiconductor device, comprising:
an active pattern on a substrate;
a gate structure crossing the active pattern;
a source/drain pattern on the active pattern at a side of the gate structure;
a contact plug on the source/drain pattern; and
a conductive pattern between the source/drain pattern and the contact plug,
wherein the source/drain pattern includes a barrier layer adjacent to the conductive pattern, and
wherein the barrier layer includes an oxygen atom.

2. The semiconductor device as claimed in claim 1, wherein a lowermost surface of the source/drain pattern is closer to the substrate than an uppermost surface of the active pattern.

3. The semiconductor device as claimed in claim 1, wherein the conductive pattern includes a metal-semiconductor compound.

4. The semiconductor device as claimed in claim 3, wherein the conductive pattern includes a metal silicide.

5. The semiconductor device as claimed in claim 1, wherein:
the source/drain pattern covers a bottom surface and side surfaces of the conductive pattern, and
the barrier layer extends in parallel with the bottom surface and the side surfaces of the conductive pattern.

6. The semiconductor device as claimed in claim 5, wherein, when viewed in cross-section, the barrier layer has a U shape.

7. The semiconductor device as claimed in claim 1, wherein the barrier layer includes silicon oxide.

8. The semiconductor device as claimed in claim 1, wherein:
the source/drain pattern further includes a semiconductor pattern doped with an impurity, and
the barrier layer is interposed between the conductive pattern and at least a portion of the semiconductor pattern.

9. The semiconductor device as claimed in claim 8, wherein the impurity includes a P-type impurity or an N-type impurity.

10. The semiconductor device as claimed in claim 8, wherein the conductive pattern is in contact with the barrier layer.

11. The semiconductor device as claimed in claim 1, further comprising a plurality of device isolation patterns on the substrate at opposite sides of the active pattern,
wherein the active pattern extends in a first direction,
wherein the gate structure extends in a second direction,
wherein the device isolation patterns are spaced apart in the second direction from each other with the active pattern interposed therebetween,
wherein the active pattern includes an active fin that is a fin-shaped active region,
wherein the active fin protrudes from upper surfaces of the device isolation patterns, and
wherein the gate structure covers opposing side surfaces of the active fin.

12. A semiconductor device, comprising:
an active pattern on a substrate;
a gate structure crossing the active pattern;
a source/drain pattern on the active pattern at a side of the gate structure; and
a conductive pattern on the source/drain pattern,
wherein the source/drain pattern includes:
a first semiconductor pattern and a second semiconductor pattern sequentially stacked on the active pattern; and
a barrier layer between the conductive pattern and at least a portion of the second semiconductor pattern, and
wherein the barrier layer includes an oxygen atom.

13. The semiconductor device as claimed in claim 12, wherein the conductive pattern includes a metal-semiconductor compound.

14. The semiconductor device as claimed in claim 12, wherein:
the second semiconductor pattern covers a bottom surface and side surfaces of the conductive pattern, and
the barrier layer extends in parallel with the bottom surface and the side surfaces of the conductive pattern.

15. The semiconductor device as claimed in claim 14, wherein, when viewed in cross-section, the barrier layer has a U shape.

16. The semiconductor device as claimed in claim 14, wherein the first semiconductor pattern covers a bottom surface and side surfaces of the second semiconductor pattern.

17. The semiconductor device as claimed in claim 16, wherein, when viewed in cross-section, the first semiconductor pattern has a U shape.

18. The semiconductor device as claimed in claim 12, wherein the first semiconductor pattern includes a material having a lattice constant that is different from a lattice constant of the second semiconductor pattern.

19. The semiconductor device as claimed in claim 12, wherein:
each of the first semiconductor pattern and the second semiconductor pattern includes an impurity having conductivity, and
a concentration of the impurity in the first semiconductor pattern is different from a concentration of the impurity in the second semiconductor pattern.

20. The semiconductor device as claimed in claim 12, wherein a lowermost surface of the source/drain pattern is closer to the substrate than an uppermost surface of the active pattern.
